(19) United States
(12) Patent Application Publication
(10) Pub. No.: US 2015/0106667 A1
(43) Pub. Date: Apr. 16, 2015

(54) SOLID STATE STORAGE DEVICE AND CONTROLLING METHOD THEREOF

(71) Applicant: Lite-On IT Corporation, Taipei City (TW)

(72) Inventors: Shih-Jia Zeng, Hsinchu (TW); Jen-Chien Fu, Hsinchu (TW); Yu-Shan Wu, Hsinchu (TW); Hsie-Chia Chang, Hsinchu (TW)

(73) Assignee: Lite-On IT Corporation, Taipei City (TW)

(21) Appl. No.: 14/133,646

(22) Filed: Dec. 19, 2013

(30) Foreign Application Priority Data
Oct. 11, 2013 (CN) 201310471811.5

(51) Int. Cl. G11C 16/34; G06F 11/10; G06F 3/06; G06F 11/07

(52) U.S. Cl. CPC G11C 16/3409; G06F 11/076; G06F 11/1008; G06F 3/0616; G06F 3/0634; G06F 3/0679
USPC 714/704; 711/103; 714/764

(57) ABSTRACT

A solid state storage device and controlling method thereof are provided, and the method includes following steps. Data is programmed into a flash memory module by using a first programming scheme. A data error parameter of the flash memory module is determined. If the data error parameter is greater than an error predefine value, the data is programmed into the flash memory module by using a second programming scheme. The first programming scheme and the second programming scheme are respectively mapping to a first threshold voltage frame and a second threshold voltage frame, and voltage interval of the second threshold voltage frame is broader than voltage interval of the first threshold voltage frame.

### CROSS-REFERENCE TO RELATED APPLICATION

This application claims the priority benefit of China application serial no. 201310471811.5, filed on Oct. 11, 2013. The entirety of the above-mentioned patent application is hereby incorporated by reference herein and made a part of this specification.

### BACKGROUND OF THE INVENTION

1. Field of the Invention

The invention relates to a solid state storage device, and particularly to a solid state storage device having a plurality of programming schemes and a controlling method thereof.

2. Description of Related Art

The growth of digital cameras, mobile phones, and MP3 players has been rapid in recent years. Consequently, the consumers' demand for storage media has increased tremendously. Since flash memory has the characteristics of non-volatility, low power consumption, small volume, non-mechanical structure, and high read-and-write speed, it is most adaptable in portable electronic products, such as laptops, digital cameras, mobile phones and so on. A solid state storage device is a storage device adopting flash memory as storage medium. Therefore, flash memory has become an important part of the electronic industries.

The flash memory used in a solid state storage device is usually a non-volatile memory element. Namely, when data is written into the flash memory, it is stored in the solid state storage device even if system power is turned off. FIG. 1 is a schematic view illustrating a flash memory unit according to the prior art. The flash memory comprises a plurality of flash memory units for storing data.

Referring to FIG. 1, a flash memory unit 1 includes a charge trapping layer 2 for storing electrons, a control gate 3 for applying a voltage, a tunnel oxide layer 4, and an interpoly dielectric layer 5. When it is intended to write data into the flash memory unit 1, electrons may be injected into the charge trapping layer 2 to change a threshold voltage of the flash memory unit 1, and a predefined value of the threshold voltage is used to define a digital storage value of the flash memory unit 1, thereby realizing a data storage function. Here, the process of injecting electrons into the charge trapping layer 2 is termed as programming. On the contrary, when it is intended to remove the stored data, the flash memory unit 1 may be restored back to a state prior to the programming process by removing the injected electrons from the charge trapping layer 2.

During programming and erasing data into and from the flash memory unit 1, the flash memory unit 1 may be deteriorated through multiple times of injection and removal, making the threshold voltage of the programmed flash memory unit 1 unable to be maintained and become deviated. Once the threshold voltage of the programmed flash memory unit 1 is deviated, a storage state of the programmed flash memory unit 1 may not be correctly identified, thus having error bits. Besides, through multiple times of programming and erasing data into and from the flash memory unit 1, the lifetime of the flash memory unit 1 is gradually shortened through deterioration of the tunnel oxide layer 4.

### SUMMARY OF THE INVENTION

The invention provides a solid state storage device and a controlling method thereof capable of setting a programming scheme according to a bit error parameter found when reading data and using different programming schemes at different stages of time to prolong lifetime of the flash memory.

The invention provides a controlling method of a solid state storage device. The solid state storage device includes a flash memory module for storing data, and the flash memory module has a plurality of memory cells. Each of the plurality of memory cells has a plurality of storage states. The controlling method includes the following steps. A first programming scheme is used to program the data into the flash memory module. A data error parameter of the flash memory module is determined. If the data error parameter exceeds an error predefine value, a second programming scheme is used to program the data into the flash memory module. The first programming scheme and the second programming scheme respectively map to a first threshold voltage frame and a second threshold voltage frame, and a voltage interval of the second threshold voltage frame is broader than a voltage interval of the first threshold voltage frame.

In an embodiment of the invention, the controlling method further includes computing at least one of a parameter of erasing times, a parameter of reading times, and a parameter of writing times of the memory cells. When the at least one of the parameter of erasing times, the parameter of reading times, and the parameter of writing times exceeds a predefined value, it is switched from the first programming scheme to the second programming scheme.

In an embodiment of the invention, the storage states include an erase state and at least one non-erase state, and the first programming scheme has at least one first verification voltage to distinguish the storage states. The second programming scheme has at least one second verification voltage to distinguish the storage states. The first verification voltage and the second verification voltage corresponding to the same storage state have different voltage values.

In an embodiment of the invention, the at least one non-erase state has a corresponding at least one first verification voltage in the first programming scheme, the at least one non-erase state has a corresponding second verification voltage in the second programming scheme. The second verification voltage is higher than the first verification voltage corresponding to the identical non-erase state.

In an embodiment of the invention, the erase state has a corresponding first threshold voltage lower limit in the first programming scheme, and the erase state has a corresponding second threshold voltage lower limit in the second programming scheme. The voltage interval of the first threshold voltage frame is categorized into a plurality of first threshold voltage sub-frames corresponding to the storage states according to the at least one first verification voltage and the first threshold voltage lower limit. The voltage interval of the second threshold voltage frame is categorized into a plurality of second threshold voltage sub-frames corresponding to the storage states according to the at least one second verification voltage and the second threshold voltage lower limit. Voltage intervals of the second threshold voltage sub-frames are broader than voltage intervals of the first threshold voltage sub-frames corresponding to the same storage state.

In an embodiment of the invention, the step of determining the data error parameter of the flash memory module includes computing a corrected bit number found when the data is read by using an error correction code (ECC), and using the corrected bit number as the data error parameter.

In an embodiment of the invention, the step of determining the data error parameter of the flash memory module includes computing a bit error rate found when the data is read, and using the bit error rate as the data error parameter.

From another perspective, the invention provides a solid state storage device, including a connector, a flash memory module, and a memory controller. The flash memory module has a plurality of memory cells, each of the memory cells having a plurality of storage states. The memory controller is coupled to the connector and the flash memory module. The memory controller uses a first programming scheme to program data into the flash memory module and determines a data error parameter of the flash memory module. If the data error parameter exceeds an error predefine value, the memory controller uses a second programming scheme to program the data into the flash memory module. The first programming scheme and the second programming scheme respectively map to a first threshold voltage frame and a second threshold voltage frame, and a voltage interval of the second threshold voltage frame is broader than a voltage interval of the first threshold voltage frame.

In view of the above, in the solid state storage device and the controlling method thereof according to the embodiments, the appropriate programming scheme is used according to the data error parameter detected when the data is read. In this way, different verification voltages are used for programming and reading data at different stages of time, thereby prolonging the lifetime of the flash memory module.

To make the above features and advantages of the invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view illustrating a flash memory unit according to the prior art.

FIG. 2 is a schematic block view illustrating a memory storage device according to an exemplary embodiment.

FIG. 3 is a schematic block diagram illustrating a flash memory module according to an exemplary embodiment.

FIG. 4 is a schematic view illustrating a memory cell array according to an exemplary embodiment.

FIG. 5 is a schematic view illustrating a relation between a storage state and a threshold voltage in a flash memory module according to an exemplary embodiment.

FIG. 6 is a schematic view illustrating programming of memory cells according to an exemplary embodiment.

FIG. 7 is another schematic view illustrating a relation between a storage state and a threshold voltage in a flash memory module according to an exemplary embodiment.

FIG. 8 is a flowchart illustrating a controlling method of a solid state storage device according to an exemplary embodiment of the invention.

FIGS. 9A and 9B are respectively schematic views illustrating a first programming scheme and a second programming scheme according to an exemplary embodiment of the invention.

FIG. 10A is a schematic view illustrating a plurality of programming schemes according to an exemplary embodiments of the invention.

FIG. 10B is a schematic view illustrating a first programming scheme and a second programming scheme according to another exemplary embodiment of the invention.

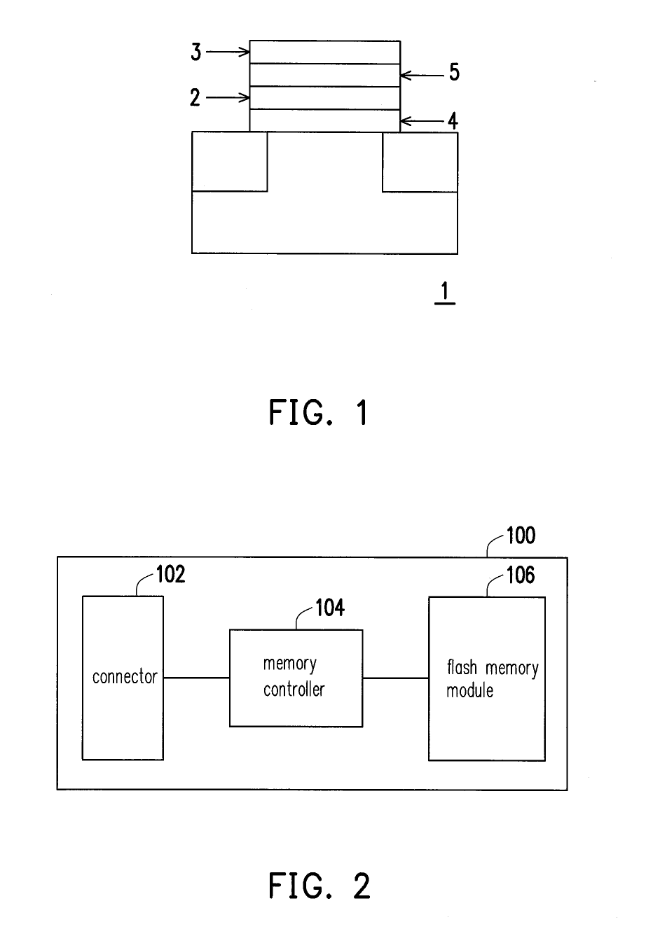

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

Generally speaking, a solid state storage device includes a flash memory module and a memory controller. The solid state storage device is usually used with a host system, so that the host system may write data into or read data from the solid state storage device.

FIG. 2 is a schematic block view illustrating a solid state storage device according to an exemplary embodiment. Referring to FIG. 2, a solid state storage device 100 includes a connector 102, a memory controller 104, and a flash memory module 106.

In this exemplary embodiment, the connector 102 is compatible with the Universal Serial Bus (USB) standard. However, it should be noted that the invention is not limited thereto. The connector 102 may also meet the Parallel Advanced Technology Attachment (PATA) standard, Institute of Electrical and Electronic Engineers (IEEE) 1394 standard, Peripheral Component Interconnect (PCI) Express standard, Secure Digital (SD) interface standard, Serial Advanced Technology Attachment (SATA) standard, Memory Stick (MS) interface standard, Multi Media Card (MMC) interface standard, Embedded Multimedia Card (eMMC) interface standard, Universal Flash Storage (UFS) interface standard, Compact Flash (CF) interface standard, Integrated Device Electronics (IDE) standard, or other compatible standards.

The memory controller 104 executes a plurality of logic gates or control commands implemented in a hardware form or in a firmware form, and performs operations of writing, reading or erasing data in the flash memory module 106 according to the command of the host system.

The flash memory module 106 is coupled to the memory controller 104 for storing data. The flash memory module 106 may be a single level cell (SLC) NAND flash memory module (i.e. a flash memory module where one memory cell stores one bit of data), a multi-level cell (MLC) NAND flash memory module (i.e. a flash memory module where one memory cell stores two bits of data), a trinary level cell (TLC) NAND flash memory module (i.e. a flash memory module where one memory cell stores three bits of data), other flash memory modules, or other memory modules having the similar characteristics.

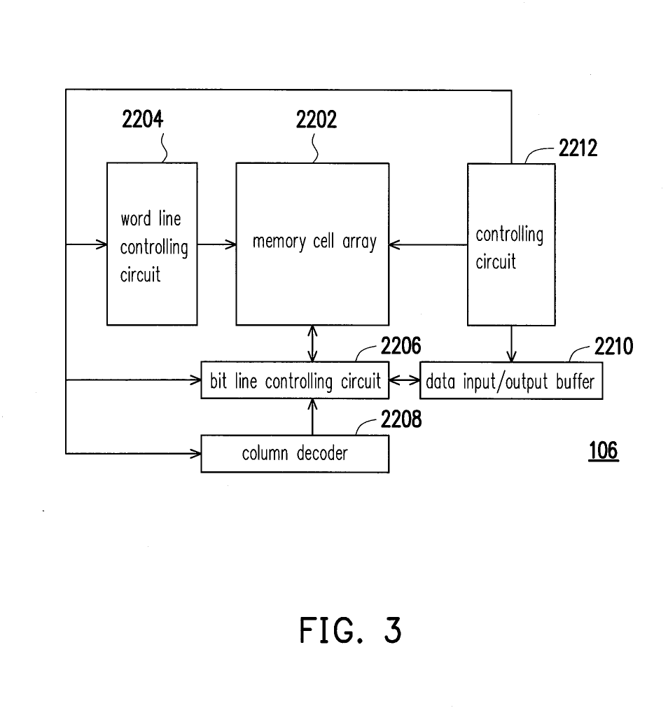

Referring to FIG. 3, the flash memory module 106 includes a memory cell array 2202, a word line controlling circuit 2204, a bit line controlling circuit 2206, a column decoder 2208, a data input/output buffer 2210, and a controlling circuit 2212.

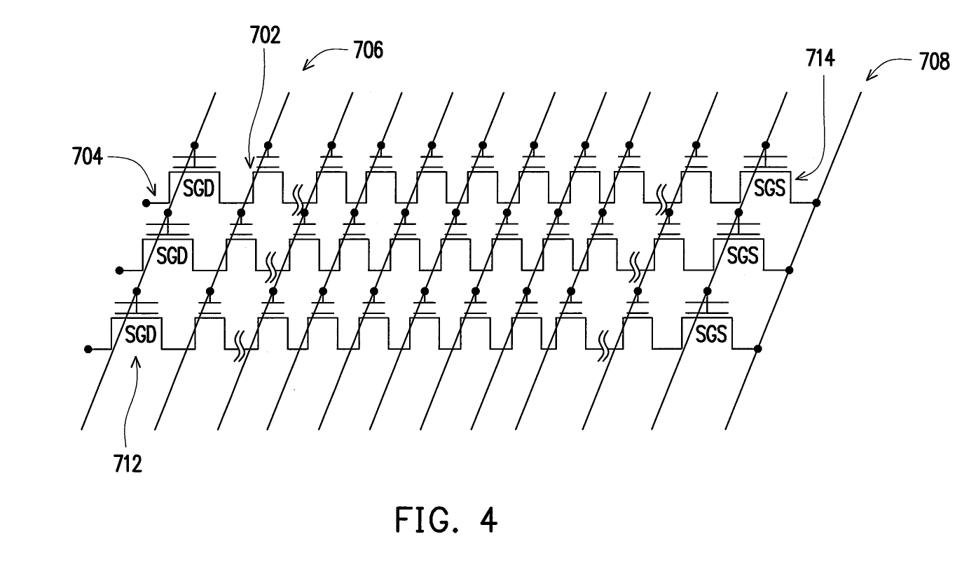

Referring to FIG. 4, the memory cell array 2202 includes a plurality of memory cells 702 for storing data, a plurality of select gate drain (SGD) transistors 712, and a plurality of select gate source (SGS) transistors 714, as well as a plurality of bit lines 704, a plurality of word lines 706, and a common source line 708 connected to the plurality of memory cells. The memory cells 702 are disposed on intersections of the bit lines 704 and the word lines 706 in an array arrangement. When receiving a writing command or a reading command from the memory controller 104, the controlling circuit 2212 controls the word line controlling circuit 2204, the bit line controlling circuit 2206, the column decoder 2208, and the data input/output buffer 2210 to write data to or read data from the memory cell array 2202. The word line controlling circuit 2204 controls a voltage applied to the word lines 706, the bit line controlling circuit 2206 controls a voltage applied to the bit lines 704, the column decoder 2208 selects a corresponding bit line according to a decoding column address in the command, and the data input/output buffer 2210 temporarily stores the data.

Memory cells in the flash memory module 106 represent bit data that are stored with a threshold voltage. Specifically speaking, each memory cell in the memory cell array 2202 has a plurality of storage states, and the storage states are distinguished with a plurality of predefined voltages.

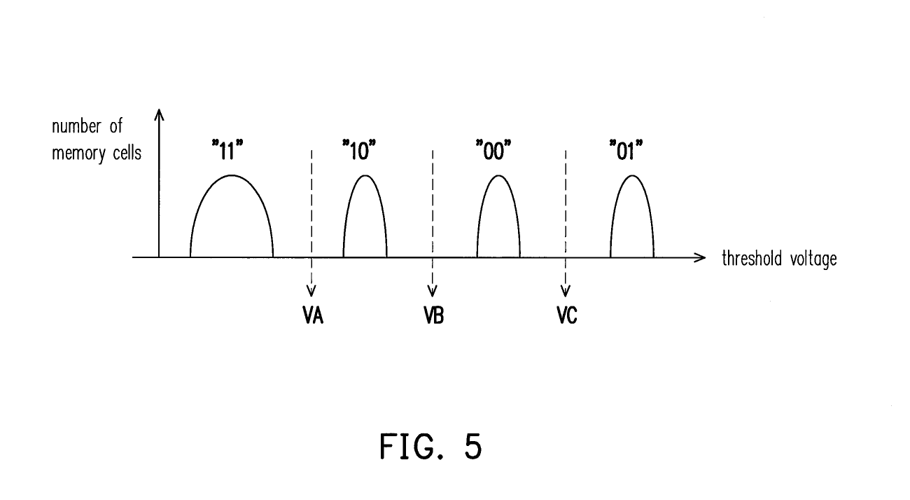

FIG. 5 is a schematic view illustrating a relation between a storage state and a threshold voltage in a flash memory module according to an exemplary embodiment. Referring to FIG. 5, taking the MLC flash memory as an example, the threshold voltage of each memory cell may serve to categorize four storage states according to a first predefined voltage VA, a second predefined voltage VB, and a third predefined voltage VC, and the storage states respectively represent bit data of “11”, “10”, “00”, and “01”. In other words, each of the storage states includes a least significant bit (LSB) and a most significant bit (MSB). In this exemplary embodiment, each memory cell is capable of storing two bits of data, so each memory cell has four storage states that are categorized with three predefined voltages. It should be noted that the corresponding relation between the threshold voltage and the storage states is only an example and does not serve to limit the invention. In another exemplary embodiment of the invention, a corresponding relation between the threshold voltage and the storage states may be arranged in an order of “11”, “10”, “01”, and “00” as the threshold voltage increases.

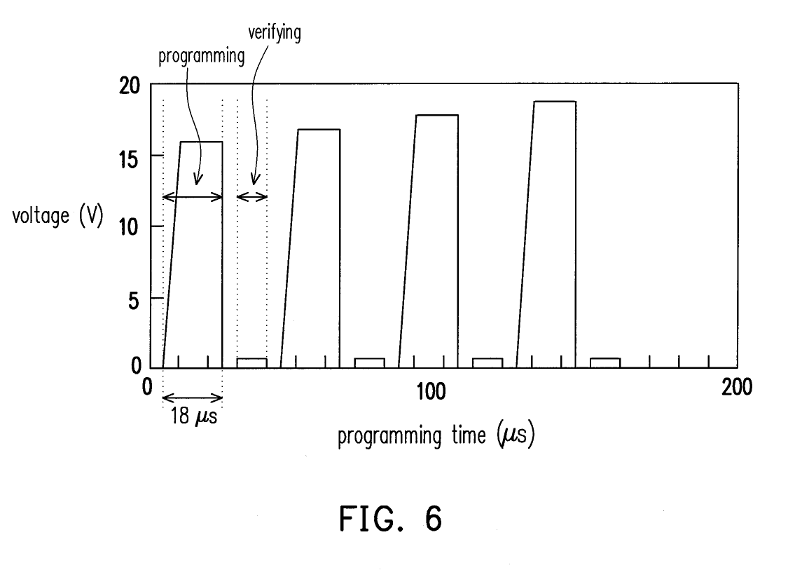

FIG. 6 is a schematic view illustrating programming of memory cells according to an exemplary embodiment. Referring to FIG. 6, in this exemplary embodiment, programming of the memory cells is manifested by providing a plurality of times of a pulse writing voltage and a plurality of verifications. Specifically speaking, when the data is to be written to the memory cells, the memory controller 104 sets the threshold voltage and a verification voltage corresponding to the data to be written, and commands the control circuit 2212 of the flash memory module 106 to program the memory cells with an initial writing voltage and a writing voltage pulse time that are predefined, so as to write the data. Afterwards, the memory controller 104 uses the verification voltage to verify the memory cells, so as to determine whether the memory cells already reach the threshold voltage as required and are in the correct storage state. If the memory cells are not programmed to reach the threshold voltage as required, the memory controller 104 commands the controlling circuit 2212 to add an incremental-step-pulse programming (ISPP) adjustment value with the writing voltage currently applied as a new writing voltage (i.e. a repeated writing voltage) and programs the memory cells again according to the new writing voltage and a new writing voltage pulse time. On the contrary, if the memory cells are already programmed to reach the threshold voltage as required, it is indicated that the data is correctly written to the memory cells. For example, the initial writing voltage may be set at 16 voltages (V), the writing voltage pulse time may be set to as 18 microseconds (μs), and the ISPP adjustment value may be set at 0.6V. However, the invention is not limited thereto.

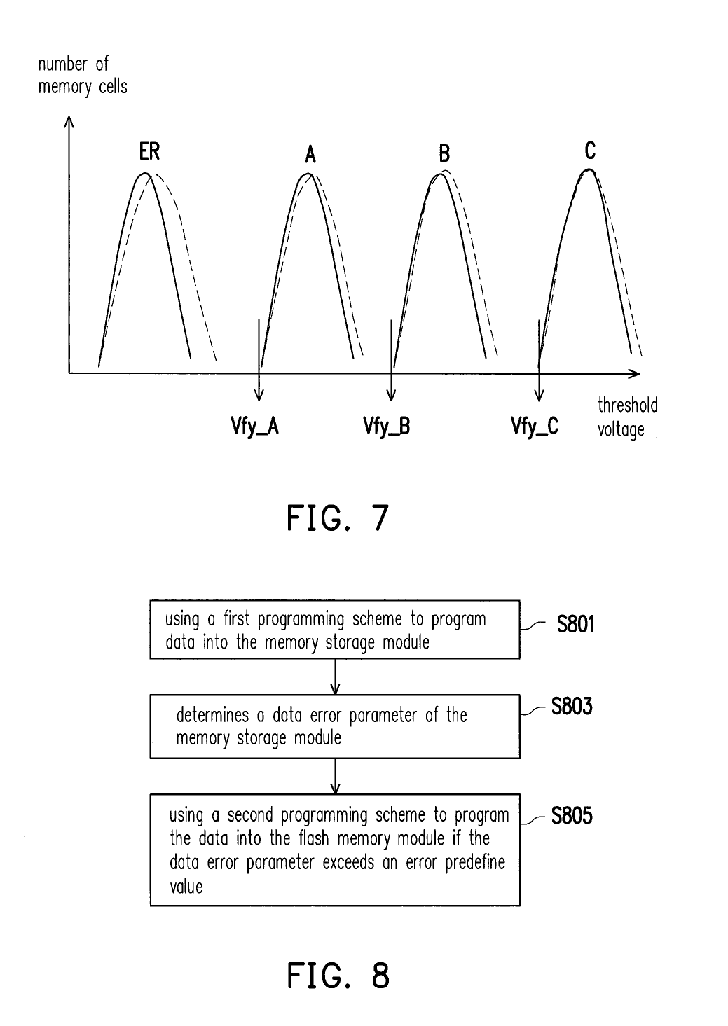

FIG. 7 is another schematic view illustrating a relation between a storage state and a threshold voltage in a flash memory module according to an exemplary embodiment. Based on the above, it is known that the memory controller 104 verifies the memory cells with the verification voltage to ensure that the memory cells are programmed to the correct storage state. Referring to solid lines in FIG. 7, and taking the MLC flash memory as an example, the threshold voltage of each memory cell may serve to categorize four storage states according to a verification voltage Vfy_A, a verification voltage Vfy_B, and a verification voltage Vfy_C. Besides, the storage states respectively represent “ER”, “A”, “B”, and “C”. For example, when the data written to the memory cell is a bit data corresponding to the storage state “C”, the memory controller 104 commands the control circuit 2212 to program the threshold voltage of the memory cell to exceed the verification voltage Vfy_C.

When the data is to be read from the memory cell, the memory controller 104 commands the controlling circuit 2212 of the flash memory module 106 to apply a predefined reading voltage set to the word line of the memory cell to be read, and determines the storage state of the memory cell according to a conductive state of the memory cell. However, multiple times of injection and removal of electrons during writing and erasing may result in deterioration of a part of the structure of the memory cells 702 of the flash memory module 106, such as deterioration of a tunnel oxide layer. Namely, the threshold voltage of the memory cells may be deviated through the multiple times of injection and removal of electrons. In other words, threshold voltage distributions of the storage states of the flash memory module consequently become broader (as shown in dotted lines in FIG. 7).

Based on the characteristics of flash memory above, the invention provides a solid state storage device having a plurality of programming schemes. The solid state storage device may choose the corresponding programming scheme to program the data into the flash memory module according to different conditions.

FIG. 8 is a flowchart illustrating a controlling method of a solid state storage device according to an embodiment of the invention. Referring to FIGS. 2, 3, and 8, the method described with this embodiment is suitable for the memory storage device 100. Details regarding the steps of the method in this embodiment are described below with the components of the memory storage device 100 in FIG. 2.

At Step 801, the memory controller 104 uses a first programming scheme to program data into the memory storage module 106. Then, at Step 803, the memory controller 104 determines a data error parameter of the memory storage module 106. At Step 805, if the data error parameter exceeds an error predefine value, the memory controller 104 uses a second programming scheme to program the data into the flash memory module 106. In this embodiment of the invention, the first programming scheme and the second programming scheme are respectively maps to a first threshold voltage frame and a second threshold voltage frame. Also, a voltage interval of the second threshold voltage frame is broader than a voltage interval of the first threshold voltage frame.

As previously described, the memory cells in the flash memory module 106 may be categorized into a plurality of storage states according to the predetermined verification voltages. In an embodiment of the invention, the threshold voltage frame may be defined as a voltage interval formed between a maximal verification voltage and a predefined voltage. In an embodiment of the invention, the predefined voltage is a threshold voltage lower limit of the erase state “ER” of the memory cells.

Nevertheless, the invention is not limited thereto. In another embodiment, the predefined voltage may be set to be a voltage value lower than the threshold voltage lower limit of the erase state “ER”.

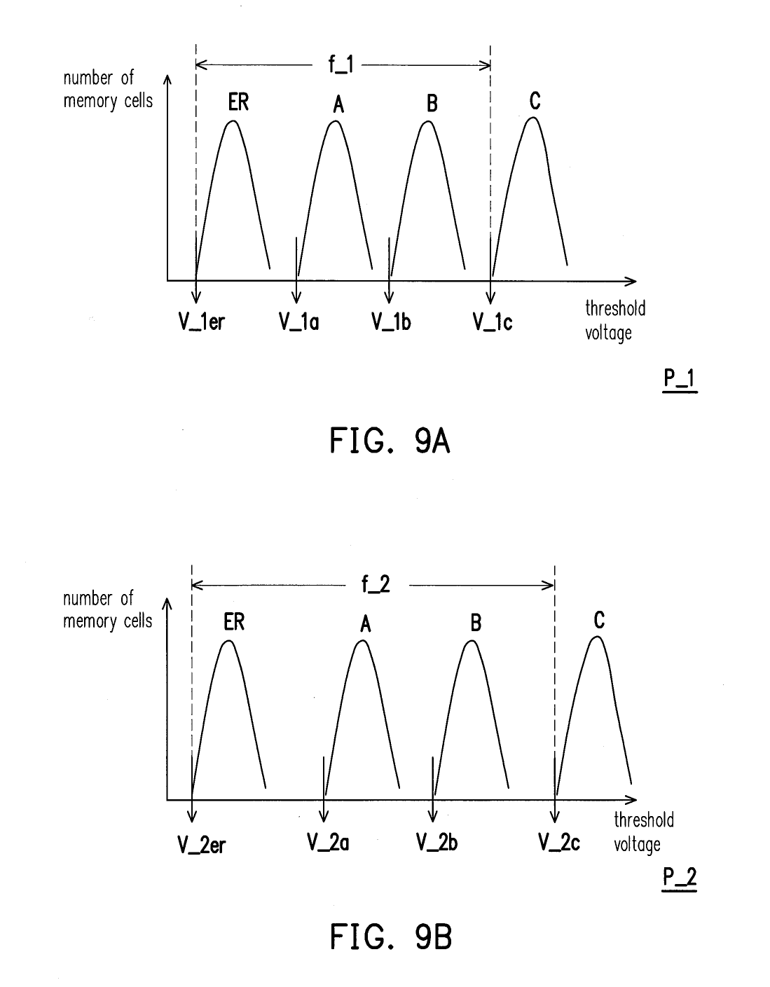

FIGS. 9A and 9B are respectively schematic views illustrating a first programming scheme and a second programming scheme according to an embodiment of the invention. In this embodiment, each programming scheme maps to a threshold voltage frame with a voltage interval formed by a threshold voltage lower limit of the erase state and a maximal verification voltage. In FIG. 9A, the memory cells in the flash memory module 106 are categorized into the four storage states “ER”, “A”, “B”, and “C” according to the three verification voltages V_1a, V_1b, and V_1c, and V_1a<V_1b<V_1c. Also, the erase state “ER” has a threshold voltage lower limit V_1er. FIG. 9A shows a first programming scheme P_1. The first programming scheme P_1 maps to a first threshold voltage frame f_1, and the first threshold voltage frame f_1 is a voltage interval formed by the threshold voltage lower limit V_1er of the erase state “ER” and the maximal verification voltage V_1c.

Besides, in FIG. 9B, the memory cells in the flash memory module 106 are categorized into the four storage states “ER”, “A”, “B”, and “C” according to three verification voltages V_2a, V_2b, and V_2c, and V_2a<V_2b<V_2c. Also, the erase state “ER” has a threshold voltage lower limit V_2er. FIG. 9B shows a second programming scheme P_2. The second programming scheme P_2 maps to a second threshold voltage frame f_2, and the second threshold voltage frame f_2 is a voltage interval formed by the threshold voltage lower limit V_2er of the erase state “ER” and the maximal verification voltage V_2c. Referring FIGS. 9A and 9B at the same time, the second threshold voltage frame f_2 is broader than the first threshold voltage frame f_1.

It should be understood based on the description of FIG. 7 that the threshold voltage distributions of the memory cells in the flash memory module 106 become broader through multiple times of injection and removal of electrons. More specifically, at an earlier stage when the solid state storage device is used, a variance of the threshold distributions of the memory cells is smaller. Relatively, at a later stage when the solid stage storage device is used, the variance of the threshold distributions of the memory cells in the flash memory module 106 becomes greater. Therefore, if the voltage interval of the threshold voltage frame is set to be too narrow in the programming scheme (i.e. the intervals between the threshold voltage distributions corresponding to the storage states are too narrow), the threshold voltage distributions of the memory cells in the flash memory module 106 may overlap at the later stage. Consequently, data reading error may occur.

On the contrary, if the voltage interval of the threshold voltage frame is defined to be too broad in the programming scheme (i.e. the intervals between the threshold voltage distributions corresponding to the storage states are too broad) in order to avoid overlapping of the threshold voltage distributions of the memory cells in the flash memory module and read the data normally, the higher threshold voltage facilitates deterioration of the tunnel oxide layer and shortens the lifetime of the flash memory module 106, even though overlapping of the threshold voltage distributions of the memory cells may be reduced. Therefore, in this embodiment of the invention, the memory controller 104 may choose the corresponding programming scheme according to different conditions to program the data into the flash memory module 106, and the different programming schemes have different threshold voltage frames. Thus, the flash memory module 106 may perform programming with the appropriate programming scheme at different stages.

In an embodiment of the invention, the data error parameter may be a bit error parameter, and the error predefine value may be an allowable threshold value. At Step 803, the memory controller 104 performs an error detection process to obtain the bit error parameter. When the bit error parameter exceeds the allowable threshold value, the memory controller 104 switches from the first programming scheme P_1 to the second programming scheme P_2, and alternatively uses the second programming scheme P_2 to program the data into the flash memory module 106. The voltage interval of the second threshold voltage frame f_2 is broader than the voltage interval of the first threshold voltage frame f_1. More specifically, when the threshold voltage distributions of the memory cells become broader, the chance of incorrect categorization under the same programming scheme increases as well, and the bit error parameter of data bits increases as well. Therefore, when the memory controller 104 finds that the bit error parameter exceeds the allowable threshold value, the memory controller 104 switches from the first programming scheme P_1 to the second programming scheme P_2 with a broader threshold voltage frame, so as to improve the chance of data reading error. In this embodiment of the invention, the bit error parameter is a corrected bit number or a bit error rate (RBER).

Specifically speaking, the memory controller 104 usually has an error correction unit (ECU) for performing an error checking and correcting process to ensure data correctness. In this exemplary embodiment, when the memory controller 104 receives a writing command from the host system, the error correction unit generates a corresponding error checking and correcting (ECC) code for the data corresponding to the writing command, and the memory controller 104 writes the data corresponding to the writing command and the corresponding error checking and correcting code into the flash memory module 106. Then, when the memory controller 104 reads the data from the flash memory module 106, the memory controller 104 simultaneously reads the error checking and correcting code corresponding to the data, and the error correction unit performs the error checking and correcting process to the data that is read according to the error checking and correcting code.

Specifically, the error correction unit is designed to be capable of correcting a certain number of error bits (the number is referred to as the maximally correctable error bit number). For example, the maximally correctable error bit number is 24. If a number of error bits in the data being read is no more than 24, the error correction unit is capable of correcting the error bits back to correct values according to the error correcting code. Namely, the data is error-correctable. If the number of error bits in the data being read is more than 24, the error correction unit reports a failure of error correction. Namely, the data is not error-correctable.

Therefore, in the exemplary embodiment described herein, the memory controller 104 computes the corrected bit number found when the data being read is read according to the error checking and correcting code, and determines whether the corrected bit number exceeds an allowable threshold value. When the corrected bit number exceeds the allowable threshold value, the first programming scheme P_1 is switched to the second programming scheme P_2. In this embodiment, the allowable threshold value may be the maximally correctable error bit number of the ECU or a value smaller than the maximally correctable error bit number. For example, given that the maximally correctable error bit number is 24, the allowable threshold value may be set at a value equal to or less than 24. Namely, when the memory controller 104 is still capable of correcting the data back to the original and correct data, it is not necessary for the memory controller 104 to switch the programming scheme. However, once the corrected bit number gradually increases, it is indicated that the memory controller 104 may not be capable of accurately restoring the data. At this time, the memory controller 104 switches to a programming scheme having a broader threshold voltage breadth to avoid incorrect reading of data.

In another embodiment, the memory controller 104 may also compute the bit error rate found when the data being read is read and determines whether the bit error rate exceeds the allowable threshold value. When the bit error rate exceeds the allowable threshold value, the first programming scheme P_1 is switched to the second programming scheme P_2. However, even though the embodiment described above uses the data error parameter as a criterion for switching the programming scheme, the memory controller 104 may also switch the programming scheme with other determination mechanisms in another embodiment. For example, the memory controller 104 may compute at least one of a parameter of erasing times, a parameter of reading times, and a parameter of writing times of the memory cells in the flash memory module 106. When the at least one of the parameters of erasing, reading, and writing times exceeds a predefined value, the memory controller 104 switches from the first programming scheme P_1 to the second programming scheme P_2. Therefore, the memory controller 104 may use different programming schemes to program the data into the flash memory module 106 at different stages.

Based on the above, it is understood that at the earlier stage when the memory storage device is used, the variance of the threshold voltage distributions of the memory cells in the flash memory module 106 is smaller, so it does not require a broad interval between the threshold voltages of the storage states. Consequently, a threshold voltage frame of an initial programming scheme may be set with a narrower voltage interval. Namely, the memory cells may be programmed into a storage state as required with a smaller programming voltage value, and the smaller programming voltage value may slow down deterioration of the oxide layer of the flash memory module 106. When the memory controller 104 determines that the data error parameter is too high, the memory controller 104 switches the programming scheme of the flash memory module 106 and uses the programming scheme having a broader voltage interval. In this way, lifetime of the solid state storage apparatus 100 may increase.

In this embodiment, each of the programming schemes has the corresponding verification voltages to distinguish the plurality of storage states. The plurality of storage states include the erase state and at least one non-erase state. In addition, in different programming schemes, voltage values of verification voltages corresponding to the same storage state are different. In other words, when the programming scheme is switched from the first programming scheme to the second programming scheme, the verification voltages corresponding to the storage states change as the voltage interval of the threshold voltage frame becomes broader. Two examples are described below for further details.

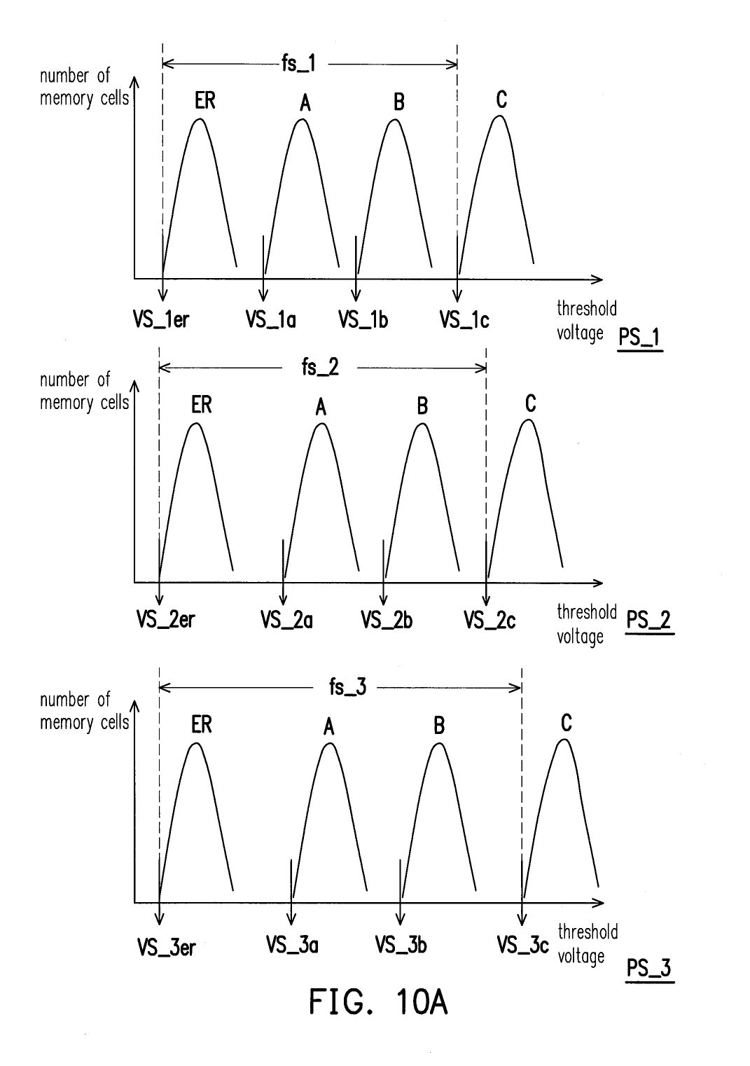

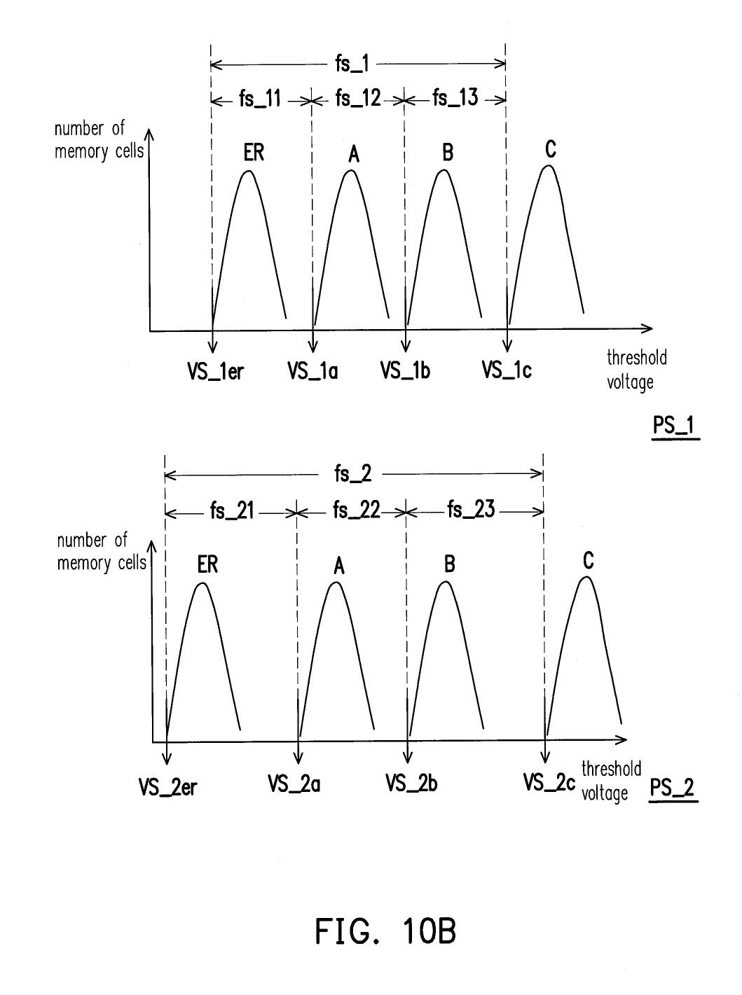

Referring to FIG. 10A, FIG. 10A is a schematic view illustrating a plurality of programming schemes according to an exemplary embodiments of the invention. In this embodiment, the solid state storage device 100 has three programming schemes PS_1, PS_2, and PS_3. A third threshold voltage frame fs_3 of the third programming scheme PS_3 is broader than a second threshold voltage frame fs_2 of the second programming scheme PS_2 and a first threshold voltage frame fs_1 of the first programming scheme PS_1, and the second threshold voltage frame fs_2 of the second programming scheme PS_2 is broader than the first threshold voltage frame fs_1 of the first programming scheme PS_1. Thus, it should be understood that the first programming scheme PS_1 has the narrowest threshold voltage frame, and the third programming scheme PS_3 has the broadest threshold voltage frame, so an order for the memory controller 104 to switch the programming schemes is from the first programming scheme PS_1 to the second programming scheme PS_2 and then to the third programming scheme PS_3.

In addition, in this embodiment, the memory controller 104 determines whether to switch from the first programming scheme PS_1 to the second programming scheme PS_2 based on whether the data error parameter exceeds a first error predefine value, and determines whether to further switch from the second programming scheme PS_2 to the third programming scheme PS_3 based on whether the data error parameter exceeds a second error predefine value. In this embodiment, the first and second error predefine values may be identical or different, and the first and second error predefine values may be set in correspondence with practical application of the data error parameter.

In this exemplary embodiment, the erase state “ER” has a corresponding threshold voltage lower limit VS_1er in the first programming scheme PS_1, a corresponding threshold voltage lower limit VS_2er in the second programming scheme PS_2, and a corresponding threshold voltage lower limit VS_3er in the third programming scheme PS_3. Besides, a non-erase state “A” has a corresponding verification voltage VS_1a in the first programming scheme PS_1, a corresponding verification voltage VS_2a in the second programming scheme PS_2, and a corresponding verification voltage VS_3a in the third programming scheme PS_3. Similarly, as shown in FIG. 10A, non-erase states “B” and “C” respectively have different corresponding verification voltages in the programming schemes PS_1, PS_2, and PS_3, so no further details in this respect will be reiterated hereinafter.

In the example shown in FIG. 10A, the threshold voltage lower limits VS_1er, VS_2er, and VS_3er corresponding to the erase state “ER” in the first, second, and third programming schemes PS_1, PS_2, and PS_3 may be the same voltage value. Besides, taking the non-erase state “A” for example, the verification voltage VS_2a corresponding to the non-erase state “A” in the second programming scheme PS_2 is higher than the verification voltage VS_1a corresponding to the non-erase state “A” in the first programming scheme PS_1, and the verification voltage VS_3a corresponding to the non-erase state “A” in the third programming scheme PS_3 is higher than the verification voltage VS_2a corresponding to the non-erase state “A” in the second programming scheme PS_2. Thus, the verification voltages corresponding to the storage state increase as the voltage intervals of the threshold voltage frames become broader, so as to react to the threshold voltage distributions of the storage states that are broadened as the time of use prolongs. Based on FIG. 10A and the description above, the respective relations of the storage states “B” and “C” with the corresponding verification voltages in the programming schemes PS_1, PS_2, and PS_3 are understood according to the description about the storage state “A”, so no further details in this respect will be reiterated hereinafter.

Referring to FIG. 10B, FIG. 10B is a schematic view illustrating the first programming scheme and the second programming scheme according to another exemplary embodiment of the invention. In this embodiment, the voltage interval of the second threshold voltage frame fs_2 of the second programming scheme PS_2 is broader than the voltage interval of the first threshold voltage frame fs_1 of the first programming scheme PS_1. The memory controller 104 uses the programming schemes by switching in an order from the first programming scheme PS_1 to the second programming scheme PS_2. In this embodiment, the voltage interval of the first threshold voltage frame fs_1 may be categorized into a plurality of first threshold voltage sub-frames fs_11 to fs_13 according to a plurality of corresponding verification voltages, and the voltage interval of the second threshold voltage frame fs_2 may be categorized into a plurality of second threshold voltage sub-frames fs_21 to fs_23 according to a plurality of corresponding verification voltages. In an embodiment, a voltage interval of a threshold voltage frame may be evenly divided into a plurality of threshold voltage sub-frames according to corresponding verification voltages. As shown in the first threshold voltage frame fs_1, voltage intervals of the plurality of threshold voltage sub-frames fs_11 to fs_13 have the same breadth. In another embodiment, a voltage interval of a threshold voltage frame may be unevenly divided into a plurality of threshold voltage sub-frames according to corresponding verification voltages. As shown in the second threshold voltage frame fs_2, voltage intervals of the plurality of threshold voltage sub-frames fs_21 to fs_3 have different breadths.

Specifically, as shown in FIG. 10B, the erase state “ER” has the corresponding threshold voltage lower limit VS_1er in the first programming scheme PS_1 and the corresponding threshold voltage lower limit VS_2er in the second programming scheme PS_2. Besides, the non-erase state “A” has the corresponding verification voltage VS_1a in the first programming scheme PS_1 and the corresponding verification voltage VS_2a in the second programming scheme PS_2. Similarly, as shown in FIG. 10B, the non-erase states “B” and “C” respectively have different corresponding verification voltages in the programming schemes PS_1, and PS_2, so no further details in this respect will be reiterated hereinafter. What differs from the example shown in FIG. 10A is that in the example shown in FIG. 10B, the threshold voltage lower limits VS_1er and VS_2er corresponding to the erase state “ER” in the programming schemes PS_1 and PS_2 may have different voltage values. It should be specifically noted that to improve incorrect reading of data caused by increasing variance of the threshold voltage distributions, the example shown in FIG. 10B determines different programming schemes by adjusting the breadths of the voltage intervals of the threshold voltage sub-frames corresponding to the storage states. Namely, in the example shown in FIG. 10B, the verification voltages corresponding to the storage states in the different programming schemes may not necessarily increase as the time of use prolongs, but the threshold voltage sub-frames corresponding to the storage states may be adjusted to threshold voltage sub-frames having broader voltage intervals as the time of use prolongs. However, the invention does not impose a limitation that the breadths of the threshold voltage sub-frames corresponding to the storage states need to be adjusted with the same degree of adjustments. The extent to which the threshold voltage sub-frames corresponding to the storage states are adjusted may be determined based on practical use.

In view of the foregoing, the controlling method of the solid state storage device and the solid state storage device provided in the invention are capable of adaptively adjusting the programming schemes according to a result of determination of the data error parameter, and the programming schemes have the threshold voltage frames with the voltage intervals of different breadths. Therefore, the deterioration of the flash memory module is slowed down, and the life time of the solid state storage device is increased. In addition, the incorrect reading of data incorrectly is improved by adaptively adjusting the programming schemes.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A controlling method of a solid state storage device, wherein the solid state storage device comprises a flash memory module for storing data, and the flash memory module has a plurality of memory cells, each of the plurality of memory cells having a plurality of storage states, the controlling method comprises:
using a first programming scheme to program the data into the flash memory module;
determining a data error parameter of the flash memory module; and
if the data error parameter exceeds an error predefine value, using a second programming scheme to program the data into the flash memory module,
wherein the first programming scheme and the second programming scheme respectively map to a first threshold voltage frame and a second threshold voltage frame, and a voltage interval of the second threshold voltage frame is broader than a voltage interval of the first threshold voltage frame.

2. The controlling method of the solid state storage device as claimed in claim 1, further comprising computing at least one of a parameter of erasing times, a parameter of reading times, and a parameter of writing times of the memory cells, when the at least one of the parameter of erasing times, the parameter of reading times, and the parameter of writing times exceeds a predefined value, switching from the first programming scheme to the second programming scheme.

3. The controlling method of the solid state storage device as claimed in claim 1, wherein each of the programming schemes has a maximal verification voltage, and the threshold voltage frame corresponding to each of the programming schemes is a voltage interval formed by the maximal verification voltage and a predefined voltage.

4. The controlling method of the solid state storage device as claimed in claim 3, wherein the storage states comprise an erase state, and the erase state corresponding to each of the programming schemes has a threshold voltage lower limit, the predefined voltage being the threshold voltage lower limit

5. The controlling method of the solid state storage device as claimed in claim 1, wherein the storage states comprise an erase state and at least one non-erase state, the first programming scheme has a corresponding at least one first verification voltage to distinguish the storage states, and the second programming scheme has a corresponding at least one second verification voltage to distinguish the storage states, the at least one first verification voltage and the at least one second verification voltage corresponding to the same storage state having different voltage values.

6. The controlling method of the solid state storage device as claimed in claim 1, wherein the storage states comprise an erase state and at least one non-erase state, the at least one non-erase state has a corresponding at least one first verification voltage in the first programming scheme, the at least one non-erase state has a corresponding at least one second verification voltage in the second programming scheme, the at least one second verification voltage being greater than the at least one first verification voltage corresponding to the identical at least one non-erase state.

7. The controlling method of the solid state storage device as claimed in claim 1, wherein the storage states comprise an erase state and at least one non-erase state, the erase state has a corresponding first threshold voltage lower limit in the first programming scheme, the erase state has a corresponding second threshold voltage lower limit in the second programming scheme, the at least one non-erase state has a corresponding at least one first verification voltage in the first programming scheme, and the at least one non-erase state has a corresponding at least one second verification voltage in the second programming scheme, and wherein the voltage interval of the first threshold voltage frame is categorized into a plurality of first threshold voltage sub-frames corresponding to the storage states according to the at least one first verification voltage and the first threshold voltage lower limit, the voltage interval of the second threshold voltage frame is categorized into a plurality of second threshold voltage sub-frames corresponding to the storage states according to the at least one second verification voltage and the second threshold voltage lower limit, voltage intervals of the second threshold voltage sub-frames being broader than voltage intervals of the first threshold voltage sub-frames corresponding to the same storage state.

8. The controlling method of the solid state storage device as claimed in claim 1, wherein the step of determining the data error parameter of the flash memory module comprises:
computing a corrected bit number found when the data is read by using an error correction code (ECC), and using the corrected bit number as the data error parameter.

9. The controlling method of the solid state storage device as claimed in claim 1, wherein the step of determining the data error parameter of the flash memory module comprises:
computing a bit error rate found when the data is read, and using the bit error rate as the data error parameter.

10. A solid state storage device, comprising:
a flash memory module, having a plurality of memory cells, each of the memory cells having a plurality of storage states; and
a memory controller, coupled to the flash memory module, the memory controller using a first programming scheme to program data into the flash memory module, determining a data error parameter of the flash memory module, and using a second programming scheme to program the data into the flash memory module when the data error parameter exceeds an error predefine value,
wherein the first programming scheme and the second programming scheme respectively map to a first threshold voltage frame and a second threshold voltage frame, and a voltage interval of the second threshold voltage frame is broader than a voltage interval of the first threshold voltage frame.

11. The solid state storage device as claimed in claim 10, wherein the memory controller further comprises computing at least one of a parameter of erasing times, a parameter of reading times, and a parameter of writing times of the memory cells, and when the at least one of the parameter of erasing times, the parameter of reading times, and the parameter of writing times exceeds a predefined value, the memory controller switches from the first programming scheme to the second programming scheme.

12. The solid state storage device as claimed in claim 10, wherein each of the programming schemes has a maximal verification voltage, and the threshold voltage frame corresponding to each of the programming schemes is a voltage interval formed by the maximal verification voltage and a predefined voltage.

13. The solid state storage device as claimed in claim 12, wherein the storage states comprise an erase state, and the erase state corresponding to each of the programming schemes has a threshold voltage lower limit, the predefined voltage being the threshold voltage lower limit.

14. The solid state storage device as claimed in claim 10, wherein the storage states comprise an erase state and at least one non-erase state, the first programming scheme has a corresponding at least one first verification voltage to distinguish the storage states, and the second programming scheme has a corresponding at least one second verification voltage to distinguish the storage states, the at least one first verification voltage and the at least one second verification voltage corresponding to the same storage state having different voltage values.

15. The solid state storage device as claimed in claim 10, wherein the memory controller comprises computing a corrected bit number found when the data is read by using an error correction code (ECC), and using the corrected bit number as the data error parameter.

16. The solid state storage device as claimed in claim 10, wherein the memory controller comprises computing a bit error rate found when the data is read, and using the bit error rate as the data error parameter.
